(19) United States
(12) Patent Application Publication
(10) Pub. No.: US 2025/0324678 A1
(43) Pub. Date: Oct. 16, 2025

(54) BIPOLAR TRANSISTOR

(71) Applicant: STMicroelectronics International N.V., Geneva (CH)

(72) Inventors: Edoardo BREZZA, Leuven (BE); Alexis GAUTHIER, Meylan (FR); Pascal CHEVALIER, Chapareillan (FR)

(73) Assignee: STMicroelectronics International N.V., Geneva (CH)

(21) Appl. No.: 19/175,155

(22) Filed: Apr. 10, 2025

(30) Foreign Application Priority Data
Apr. 12, 2024 (FR) FR2403824

(51) Int. Cl. H10D 62/00; H10D 10/01; H10D 10/40; H10D 64/23

(52) U.S. Cl. CPC H10D 62/021; H10D 10/051; H10D 10/40; H10D 64/231

(57) ABSTRACT

A bipolar transistor is manufactured using a process including the successive steps of: a) depositing a stack on a surface of a semiconductor substrate, the stack including a first insulating layer coating the semiconductor substrate and a second insulating layer coating the first insulating layer; b) forming a trench extending across the entire thickness of the stack; c) forming, in a first portion of the trench laterally delimited by the first insulating layer, a collector region of the transistor; d) widening a second portion of the trench laterally delimited by the second insulating layer; and e) forming, in the second portion of the trench, a base region of the transistor.

### PRIORITY CLAIM

This application claims the priority benefit of French Application for Patent No. 2403824, filed on Apr. 12, 2024, the content of which is hereby incorporated by reference in its entirety to the maximum extent allowable by law.

### TECHNICAL FIELD

The present disclosure generally concerns electronic devices and, in particular, bipolar transistors and their manufacturing methods.

### BACKGROUND

Bipolar transistors have been provided. Existing bipolar transistors, however, have various disadvantages.

There exists a need to overcome all or part of the disadvantages of known bipolar transistors. It would in particular be desirable to have bipolar transistors having maximum oscillation frequencies higher than those of existing bipolar transistors.

### SUMMARY

In an embodiment, a method of manufacturing a bipolar transistor comprises the following successive steps: a) depositing, on a surface of a semiconductor substrate, a stack comprising a first insulating layer coating the semiconductor substrate and a second insulating layer coating the first insulating layer; b) forming a trench extending across the entire thickness of the stack; c) forming, in a first portion of the trench laterally delimited by the first insulating layer, a collector region of the transistor; d) widening a second portion of the trench laterally delimited by the second insulating layer; and e) forming, in the second portion of the trench, a base region of the transistor.

According to an embodiment, the collector region is formed by epitaxial growth from said surface of the semiconductor substrate.

According to an embodiment, the stack further comprises a third insulating layer coating the second insulating layer, a fourth insulating layer coating the third insulating layer, and a fifth insulating layer coating the fourth insulating layer.

According to an embodiment: the first, third, and fifth layers are made of a same first material; and the second and fourth layers are made of a same second material, different from the first material.

According to an embodiment, the first material is an oxide, preferably a silicon oxide, more preferably tetraethyl orthosilicate.

According to an embodiment, the second material is a nitride, preferably a silicon nitride.

According to an embodiment, at step d), a third portion of the trench laterally delimited by the fourth insulating layer is further widened.

According to an embodiment, the method further comprises, subsequent to step d), a step of removing portions of the third insulating layer protruding into the trench.

According to an embodiment, at step e), the base region is formed by epitaxial growth from a surface of the collector region opposite to the semiconductor substrate.

According to an embodiment, at step d), the trench is widened by isotropic etching, preferably a wet etching.

In an embodiment, a bipolar transistor comprises: on a surface of a semiconductor substrate, a stack comprising a first insulating layer coating the semiconductor substrate and a second insulating layer coating the first insulating layer; a collector region of the transistor laterally delimited by the first insulating layer; and on the collector region, a base region of the transistor having substantially vertical flanks and laterally delimited by the second insulating layer, the base region having, in top view, lateral dimensions strictly greater than those of the collector region.

According to an embodiment, the transistor further comprises an emitter region having, in top view, lateral dimensions strictly smaller than those of the collector region.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1 to 13 illustrate, by side and cross-section views, simplified and partial, structures obtained at the end of successive steps of a method of manufacturing a bipolar transistor.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the various electronic devices likely to comprise the bipolar transistors of the present disclosure have not been detailed. Further, the various applications of bipolar transistors have not been detailed, the described embodiments being compatible with all or most applications using bipolar transistors, subject to possible adaptations within the abilities of those skilled in the art on reading of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively signify, unless otherwise specified, electrically insulating and electrically conductive.

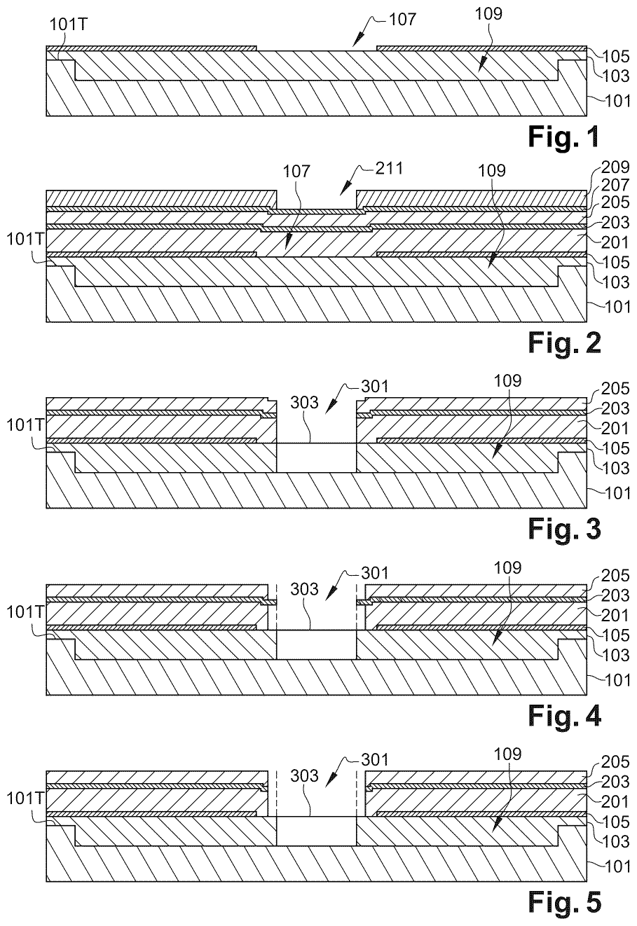

FIGS. 1 to 13 illustrate, in side and cross-section views, simplified and partial, structures obtained at the end of successive steps of a method of manufacturing a bipolar transistor 100.

In the shown example, bipolar transistor 100 is formed inside and on top of a semiconductor substrate 101. Semiconductor substrate 101 is, for example, a wafer or a piece of wafer made of a semiconductor material, for example silicon. Semiconductor substrate 101 is, for example, doped with a first conductivity type, for example type N. As an example, semiconductor substrate 101 is doped by ion implantation, for example by using phosphorus ions in the case where semiconductor substrate 101 is made of N-type doped silicon.

FIG. 1 illustrates a structure obtained at the end of successive steps of deposition of an insulating layer 103 on semiconductor substrate 101, deposition of a semiconductor layer 105 on insulating layer 103, and forming of an opening 107 in semiconductor layer 105.

The step of deposition of insulating layer 103 is, for example, preceded by a step of forming of a trench 109 in semiconductor substrate 101. In the illustrated example, trench 109 extends vertically, into the thickness of semiconductor substrate 101, from an upper surface 101T of substrate 101 down to a depth strictly smaller than the thickness of substrate 101. Further, trench 109, for example, extends laterally along a substantially horizontal main direction orthogonal to a conduction direction of bipolar transistor 100. In this example, the conduction direction of bipolar transistor 100 is substantially horizontal and orthogonal to the cross-section plane of FIGS. 1 to 13. As an example, trench 109 has a depth in the order of a few tens of nanometers, for example equal to approximately 50 nm.

The step of deposition of insulating layer 103 is, for example, further preceded by a step of cleaning of the upper surface 101T of semiconductor substrate 101, for example a wet cleaning using a hydrochloric acid solution.

Insulating layer 103 is then deposited on the side of the upper surface 101T of semiconductor substrate 101, for example on top of and in contact with surface 101T. In the shown example, insulating layer 103 is more precisely located on top of and in contact with the flanks and the bottom of trench 109, and extends laterally on top of and in contact with portions of the upper surface 101T of semiconductor substrate 101 located on either side of trench 109. In the shown example, insulating layer 103 fills, that is, totally fills, trench 109. A portion of insulating layer 103 inside of trench 109 forms an insulating trench, for example a trench of super shallow trench insulation (SSTI) type. Insulating layer 103 is made of an oxide, for example a silicon oxide. As an example, insulating layer 103 is made of tetraethyl orthosilicate (TEOS). Insulating layer 103 has, for example vertically in line with the portions of the upper surface 101T of semiconductor substrate 101 located on either side of trench 109, a thickness in the range from 10 to 30 nm, for example equal to approximately 20 nm.

Semiconductor layer 105 is then deposited on the side of the upper surface 101T of semiconductor substrate 101, for example over the entire upper surface of the structure. Semiconductor layer 105 covers insulating layer 103. In the shown example, semiconductor layer 105 is more precisely located on top of and in contact with a surface of insulating layer 103 opposite to semiconductor substrate 101 (the upper surface of layer 103, in the orientation of FIG. 1). Semiconductor layer 105 is, for example, made of the same material as semiconductor substrate 101, for example made of silicon. As an example, semiconductor layer 105 has an amorphous structure, while semiconductor substrate 101 has a crystalline structure, for example monocrystalline. Semiconductor layer 105 is, for example, doped with a second conductivity type—type P, in this example—opposite to the first conductivity type. In the case where semiconductor layer 105 is made of P-type doped silicon, the doping is, for example, due to the presence of boron in semiconductor layer 105. As an example, semiconductor layer 105 has a thickness in the range from 5 to 20 nm, for example equal to approximately 10 nm.

A thermal anneal step is then, for example, implemented. At the end of the anneal, semiconductor layer 105 has, for example, a polycrystalline structure. Semiconductor layer 105 is, for example, made of polysilicon after annealing is performed.

The anneal step is preceded, for example, by a step of cleaning of semiconductor layer 105, for example, a wet cleaning using a hydrochloric acid solution.

Opening 107 is then formed in semiconductor layer 105, for example by photolithography and then etching. In the shown example, opening 107 is located vertically in line with trench 109. Opening 107 extends vertically, from a surface of semiconductor layer 105 opposite to semiconductor substrate 101 (the upper surface of layer 105, in the orientation of FIG. 1), across the entire thickness of layer 105. In this example, opening 107 laterally separates two portions of semiconductor layer 105. Opening 107 extends, for example, laterally along a main direction substantially parallel to that of trench 109. In the shown example, opening 107 has, in top view, a width strictly smaller than that of trench 109. The width of opening 107, or of trench 109, corresponds to a lateral dimension of the opening, or of the trench, measured along a substantially horizontal direction orthogonal to the conduction direction of bipolar transistor 100 (parallel to the cross-section plane of FIG. 1). Opening 107 has, for example, a depth substantially equal to the thickness of semiconductor layer 105. Although this has not been detailed in FIG. 1, the forming of opening 107 may, in practice, lead to a partial removal of insulating layer 103 at the bottom of opening 107. In this case, opening 107 has a depth strictly greater than the thickness of semiconductor layer 105.

FIG. 2 illustrates a structure subsequently obtained at the end of successive steps of deposition of insulating layers 201, 203, 205, and 207 on the upper face side of the structure of FIG. 1, of deposition of a resist layer 209 on insulating layer 207, and of forming of an opening 211 in resist layer 209.

The step of deposition of insulating layer 201 is, for example, preceded by a step of cleaning of the upper surface of the structure, for example, a wet cleaning using a hydrochloric acid solution.

Insulating layer 201 is then deposited on the side of surface 101T of semiconductor substrate 101, for example over the entire upper surface of the structure. Insulating layer 201 coats the flanks and the bottom of opening 107, and coats the portions of semiconductor layer 105. In the shown example, insulating layer 201 is more precisely located on top of and in contact with a portion of a surface of insulating layer 103 exposed at the bottom of the opening 107 (a portion of the upper surface of layer 103, in the orientation of FIG. 2), and on top of and in contact with the side and upper surfaces of the portions of semiconductor layer 105. In the shown example, insulating layer 201 fills, that is, totally fills, opening 107. Insulating layer 201 is, for example, made of a nitride, for example a silicon nitride. As an example, insulating layer 201 has a thickness in the order of several tens of nanometers, for example equal to approximately 60 nm.

Insulating layer 203 is then deposited on the side of surface 101T of semiconductor substrate 101, for example over the entire upper surface of the structure. Insulating layer 203 coats insulating layer 201. In the shown example, insulating layer 203 is more precisely located on top of and in contact with a surface of insulating layer 201 opposite to semiconductor substrate 101 (the upper surface of layer 201, in the orientation of FIG. 2). Insulating layer 203 is, for example, made of the same material as insulating layer 103. Insulating layer 203 is, for example, made of an oxide, for example a silicon oxide, for example tetraethyl orthosilicate. As an example, insulating layer 203 has a thickness in the range from 10 and 20 nm, for example equal to approximately 12 nm.

The step of deposition of insulating layer 203 is, for example, preceded by a step of cleaning of the upper surface of the structure, for example a wet cleaning using a hydrochloric acid solution.

Insulating layer 205 is then deposited on the side of surface 101T of semiconductor substrate 101, for example over the entire upper surface of the structure. Insulating layer 205 coats insulating layer 203. In the shown example, insulating layer 205 is more precisely located on top of and in contact with a surface of insulating layer 203 opposite to semiconductor substrate 101 (the upper surface of layer 203, in the orientation of FIG. 2). Insulating layer 205 is, for example, made of the same material as insulating layer 201. Insulating layer 205 is, for example, made of a nitride, for example a silicon nitride. As an example, insulating layer 205 has a thickness in the order of several tens of nanometers, for example equal to approximately 45 nm.

Insulating layer 207 is then deposited on the side of surface 101T of semiconductor substrate 101, for example over the entire upper surface of the structure. Insulating layer 207 coats insulating layer 205. In the shown example, insulating layer 207 is more precisely located on top of and in contact with a surface of insulating layer 205 opposite to semiconductor substrate 101 (the upper surface of layer 205, in the orientation of FIG. 2). Insulating layer 207 is, for example, made of the same material as insulating layer 203. Insulating layer 207 is, for example, made of an oxide, for example a silicon oxide, for example tetraethyl orthosilicate. As an example, insulating layer 207 has a thickness in the range from 10 to 20 nm, for example equal to approximately 12 nm.

Resist layer 209 is then deposited on the side of surface 101T of semiconductor substrate 101, for example over the entire upper surface of the structure. Resist layer 209 coats insulating layer 207. In the shown example, resin layer 209 is more precisely located on top of and in contact with a surface of insulating layer 207 opposite to semiconductor substrate 101 (the upper surface of layer 207, in the orientation of FIG. 2).

Although this has not been detailed in FIG. 2, resist layer 209 may have a multilayer structure, for example resulting from successive depositions of resist layers having different chemical compositions.

Opening 211 is then formed in resist layer 209, for example by photolithography and then etching. In the shown example, opening 211 is located vertically in line with trench 109. Opening 211 extends vertically, from a surface of resist layer 209 opposite to semiconductor substrate 101 (the upper surface of layer 209, in the orientation of FIG. 2), across the entire thickness of layer 209. In this example, opening 211 laterally separates two portions of resist layer 209. Opening 211 laterally extends, for example, along a main direction substantially parallel to that of trench 109. In the shown example, the width of opening 211 has, in top view, a width strictly smaller than those of trench 109 and of opening 107. Opening 211 has a depth, for example, substantially equal to the thickness of resist layer 209.

FIG. 3 illustrates a structure subsequently obtained at the end of successive steps of forming of a trench 301 as an extension of opening 211, of removal of resist layer 209 and of insulating layer 207, and of forming of a collector region 303 of bipolar transistor 100 in a portion of trench 301 laterally delimited by insulating layer 103.

Trench 301 is formed vertically in line with opening 211, the flanks of trench 301 being located, for example, substantially in line with the flanks of opening 211. Trench 301 is, for example, formed by plasma etching, for example using an oxygen-based plasma. Trench 301 extends vertically, for example, from a surface of insulating layer 207 opposite to semiconductor substrate 101 (the upper surface of layer 207, in the orientation of FIG. 3), across the entire thickness of insulating layers 207, 205, 203, 201, and 103. In this example, trench 301 laterally separates two portions of a stack comprising insulating layers 103, 201, 203, 205, and 207. At the end of this step, a portion of surface 101T of semiconductor substrate 101 located in trench 109 is exposed at the bottom of trench 301.

Trench 301 extends laterally, for example, along a main direction substantially parallel to that of opening 211. In the shown example, trench 301 has, in top view, lateral dimensions substantially equal to those of opening 211. Trench 301 has a depth, for example, substantially equal to the thickness of the stack of insulating layers 103, 201, 203, 205, and 207. As an example, trench 301 has a depth in the order of one or more hundred nanometers, for example equal to approximately 200 nm, and a width in the order of one or more hundred nanometers, for example equal to approximately 200 nm. The width of trench 301 corresponds to a lateral dimension of the trench measured along a substantially horizontal direction orthogonal to the conduction direction of bipolar transistor 100 (parallel to the cross-section plane of FIG. 3).

Resist layer 209 and insulating layer 207 are then removed, for example simultaneously removed.

The collector region 303 of transistor 100 is then formed, for example by epitaxial growth from the portion of surface 101T of semiconductor substrate 101 exposed at the bottom of trench 301. In the shown example, the collector region is located on top of and in contact with the portion of surface 101T of semiconductor substrate 101 exposed at the bottom of trench 301, and on top of and in contact with at least a portion of the flanks of insulating layer 103 inside of trench 301. The collector region 303 of transistor 100 is made of a semiconductor material, for example the same material as semiconductor substrate 101, for example silicon. Collector region 303 is doped with the same conductivity type as semiconductor substrate 101—type N, in this example. Collector region 303 for example has a doping level strictly lower than that of semiconductor substrate 101. As an example, the dopant species of semiconductor substrate 101—for example phosphorus in the case where semiconductor substrate 101 is N-type doped silicon—diffuse into collector region 303.

Collector region 303 is, for example, formed by exposing the structure to a gaseous precursor of the semiconductor material of collector region 303, for example dichlorosilane. This for example enables to achieve a selective growth from the silicon regions (from the portion of the upper surface of semiconductor substrate 101 exposed at the bottom of trench 301, in the shown example) and not from the insulating regions (from the portions of layer 205, in the shown example).

Collector region 303 has a thickness, for example, substantially equal to that of insulating layer 103. As an example, collector region 303 has a thickness equal to approximately 70 nm. FIG. 3 illustrates an example in which collector region 303 has a thickness equal to that of insulating layer 103. In this case, collector region 303 is flush with a surface of insulating layer 103 opposite to semiconductor substrate 101 (the upper surface of layer 103, in the orientation of FIG. 3). However, this example is not limiting and collector region 303 may, as a variant, have a thickness strictly smaller than that of insulating layer 103.

The step of forming of collector region 303 is, for example, preceded by a step of cleaning of the upper surface of the structure, for example a wet cleaning using a hydrochloric acid solution.

Region 303 more specifically is, for example, an intrinsic collector region of bipolar transistor 100.

In the shown example, collector region 303 has substantially vertical flanks.

FIG. 4 illustrates a structure obtained at the end of a step of widening of a portion of trench 301 laterally delimited by insulating layer 201 and of a portion of trench 301 laterally delimited by insulating layer 205. In FIG. 4, dotted vertical lines symbolize the position of the flanks of trench 301 prior to the widening step.

At the end of the step of widening of trench 301, the portion of trench 301 laterally delimited by the flanks of insulating layer 201 has a width strictly greater than that of collector region 303. Further, in the shown example, the portion of trench 301 laterally delimited by the flanks of insulating layer 205 has a width strictly greater than that of collector region 303.

The widening of trench 301 is, for example, performed by etching of the flanks of insulating layers 201 and 205 located inside of trench 301. The etching is, for example, isotropic, for example a wet etching, enabling to selectively etch the material of insulating layers 201 and 205. The step of widening of trench 301 is, for example, interrupted before the portions of semiconductor layer 105 are exposed inside of trench 301. In other words, the step of widening of trench 301 is controlled so that the portions of trench 301 laterally delimited by the flanks of layers 201 and 205 have, after widening, a width strictly smaller than that of opening 107. After widening, the flanks of trench 301 are each laterally separated from the opposite portion of semiconductor layer 105 by a portion of insulating layer 201.

FIG. 5 illustrates a structure obtained at the end of an optional step of widening of a portion of trench 301 laterally delimited by insulating layer 203. At the end of this step, the portion of trench 301 laterally delimited by the flanks of insulating layer 203 has a width strictly greater than that of collector region 303.

The widening of trench 301 is, for example, performed by etching of the portions of insulating layer 203 protruding into trench 301. The etching is, for example, an isotropic etching, for example a wet etching enabling to selectively etch the material of insulating layer 203. The widening of the portion of trench 301 laterally delimited by insulating layer 203 is, for example, interrupted when the flanks of insulating layer 203 located inside of trench 301 are substantially vertically aligned with respect to the flanks of insulating layers 201 and 205.

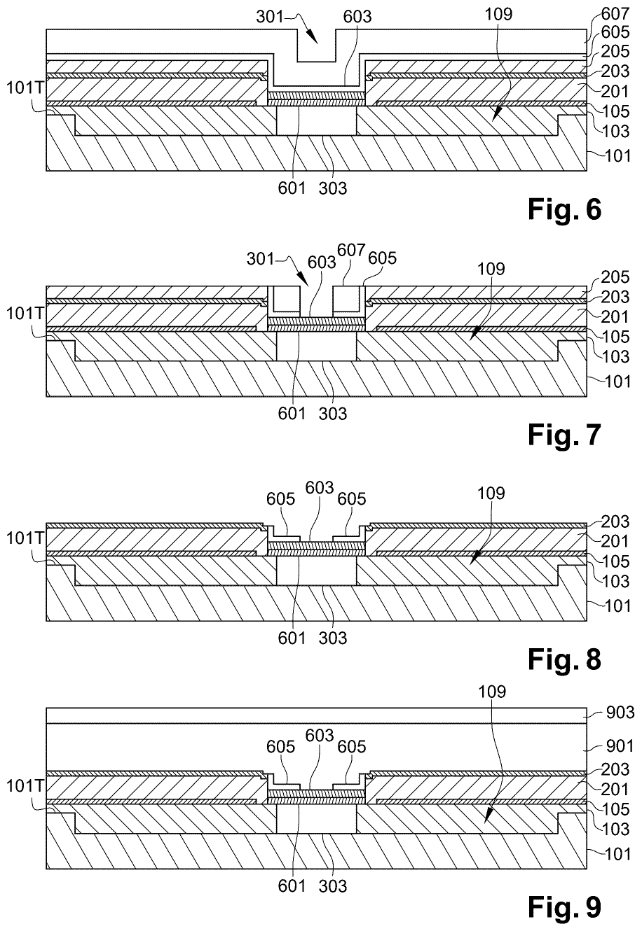

FIG. 6 illustrates a structure subsequently obtained at the end of successive steps of forming of a base region 601 of bipolar transistor 100 in a portion of trench 301 laterally delimited by insulating layer 201, of optional forming of a semiconductor region 603 on base region 601, and of deposition of insulating layers 605 and 607.

The base region 601 of transistor 100 is, for example, formed by epitaxial growth from the upper surface of collector region 303. In the shown example, base region 601 is located on top of and in contact with the upper surface of collector region 303 and on top of and in contact with portions of the upper face of insulating layer 103 exposed at the bottom of trench 301. The base region 601 of transistor 100 is made of a semiconductor material, for example the same material as semiconductor substrate 101, for example silicon. Base region 601 is doped with the second conductivity type—type P, in this example. As an example, base region 601 is doped with germanium in the case where base region 601 is made of P-type doped silicon.

Base region 601 is, for example, formed by exposing the structure to a gaseous precursor of the semiconductor material of base region 601, for example comprising dichlorosilane in the case where base region 601 is made of silicon. This enables, for example, to perform a selective growth from the silicon regions (from the upper surface of collector region 303, in the shown example) and not from the insulating regions (from the portions of layer 205, in the shown example). Due to the prior widening of trench 301, the growth from collector region 303 is further performed laterally until reaching the flanks of trench 301. Base region 601 has a thickness, for example, strictly smaller than that of insulating layer 201.

Region 601 more precisely is, for example, an intrinsic base region of bipolar transistor 100.

Optional semiconductor region 603 is then, for example, formed by epitaxial growth from the upper surface of base region 601. In the shown example, semiconductor region 603 is located on top of and in contact with the upper surface of base region 601. Semiconductor region 603 is, for example, made of the same material as semiconductor substrate 101, for example silicon. Semiconductor region 603 is, for example, non-doped. Semiconductor region 603 is, for example, a buffer layer between base region 601 and a semiconductor region having a doping type opposite to that of base region 601 and subsequently formed on top of and in contact with semiconductor region 603. Semiconductor region 603 is used to set a PN junction between these two semiconductor regions.

Insulating layer 605 is then deposited on the side of the upper surface 101T of semiconductor substrate 101, for example over the entire upper surface of the structure. Insulating layer 605 coats the flanks and the bottom of trench 301 and insulating layer 205. In the shown example, insulating layer 605 is more precisely located on top of and in contact with flanks of insulating layers 201, 203, and 205 inside of trench 301, and on top of and in contact with surfaces (upper surfaces, in the orientation of FIG. 6) of the portions of insulating layer 205 located on either side of trench 301. Insulating layer 605 is, for example, made of the same material as insulating layer 103. Insulating layer 605 is, for example, made of an oxide, for example a silicon oxide, for example tetraethyl orthosilicate.

Insulating layer 607 is then deposited on the side of surface 101T of semiconductor substrate 101, for example over the entire upper surface of the structure. Insulating layer 607 coats insulating layer 605. In the shown example, insulating layer 607 is more precisely located on top of and in contact with a surface of insulating layer 605 opposite to semiconductor substrate 101 (the upper surface of layer 605, in the orientation of FIG. 6). Insulating layer 607 is, for example, made of the same material as insulating layer 201. Insulating layer 607 is, for example, made of a nitride, for example a silicon nitride.

In the shown example, the stack formed by insulating layers 605 and 607 does not fill, that is, does not totally fill, trench 301.

FIG. 7 illustrates a structure subsequently obtained at the end of successive steps of etching of insulating layers 607 and 605.

Insulating layer 607 is, for example, etched so as to remove portions of layer 607 located on the portions of insulating layer 205 and on a central portion of the bottom of trench 301. At the end of the etching, there remain, for example inside of trench 301, two separate portions of insulating layer 607, respectively coating opposite flanks of trench 301. In the shown example, the portions of layer 607 are flush with the upper surface of insulating layer 205.

Insulating layer 605 is then etched, for example, so as to remove portions of layer 605 not coated by the portions of insulating layer 607. In the shown example, there remain two separate portions of insulating layer 605 respectively coating opposite flanks of trench 301.

The portions of insulating layer 605 for example have, in a side view, an L shape, each comprising a horizontal portion located on top of and in contact with semiconductor region 603 and a vertical portion, substantially orthogonal to the horizontal portion, located on top of and in contact with the flanks of insulating layers 201, 203, and 205 inside of opening 301.

The portions of insulating layer 605 and 607 form spacers for example.

As an example, the thickness of insulating layer 201 is selected so that the horizontal portions of the portions of insulating layer 605 are flush with the upper surface of insulating layer 203. This enables to facilitate subsequent steps of etching of the portions of insulating layer 605.

FIG. 8 illustrates a structure subsequently obtained at the end of successive steps of removal of insulating layers 607 and 205, and of removal, at least partial, of the vertical portions of the Ls formed by the portions of insulating layer 605.

In the shown example, insulating layers 205 and 607 are fully removed, for example by etching. Further, in this example, the vertical portions of the Ls formed by the portions of insulating layer 605 are etched so that the portions of insulating layer 605 are flush with the upper face of insulating layer 203. This example is, however, not limiting, and as a variant the portions of insulating layer 605 may protrude from the upper surface of insulating layer 203.

FIG. 9 illustrates a structure subsequently obtained at the end of steps of successive deposition of a semiconductor layer 901 and of an insulating layer 903.

Semiconductor layer 901 is deposited on the side of surface 101T of semiconductor substrate 101, for example over the entire upper surface of the structure. Semiconductor layer 901 coats insulating layer 203, the portions of insulating layer 605 and a portion of semiconductor region 603 not coated by the portions of insulating layer 605. In the shown example, semiconductor layer 901 is more specifically located on top of and in contact with the upper surface of insulating layer 203, on top of and in contact with the upper surfaces and the flanks of the portions of insulating layer 605, and on top of and in contact with the portion of the upper surface of semiconductor region 603 not coated by the portions of insulating layer 605. In the shown example, semiconductor layer 901 fills, that is totally fills, trench 301. Semiconductor layer 901 is, for example, made of the same material as semiconductor substrate 101, for example made of silicon. After its deposition, semiconductor layer 901 has, for example, a polycrystalline structure above the insulating regions and a monocrystalline structure above semiconductor region 603. Semiconductor layer 901 is, for example, doped with the first conductivity type—type N, in this example.

Insulating layer 903 is then deposited on the side of surface 101T of semiconductor substrate 101, for example over the entire upper surface of the structure. Insulating layer 903 coats semiconductor layer 901. In the shown example, insulating layer 903 is more specifically located on top of and in contact with a surface of semiconductor layer 901 opposite to semiconductor substrate 101 (the upper surface of layer 901, in the orientation of FIG. 9). Insulating layer 903 is, for example, made of the same material as insulating layer 103. Insulating layer 903 is, for example, made of an oxide, for example a silicon oxide, for example tetraethyl orthosilicate.

For simplification purposes, the upper surfaces of semiconductor layer 901 and of insulating layer 903 have been shown in FIG. 9 as being substantially planar. This example is however not limiting, and the upper surfaces of layers 901 and 903 may, in practice, be non-planar, for example due to the fact that layers 901 and 903 follow the relief of the upper surface of the structure on which they are deposited.

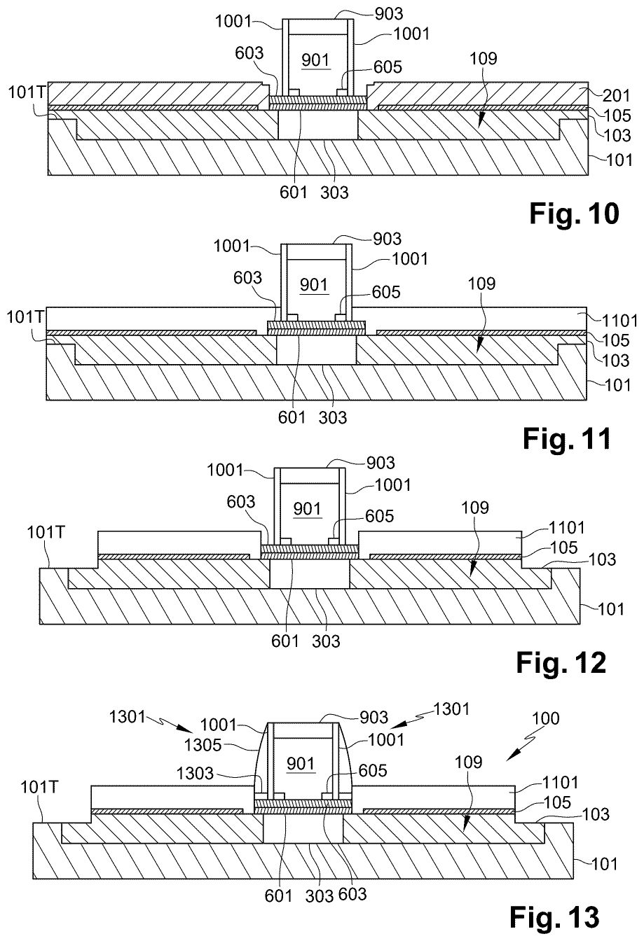

FIG. 10 illustrates a structure subsequently obtained at the end of successive steps of structuring of the insulating layer 903 and of semiconductor layer 901, of removal of insulating layer 203, of deposition of an insulating layer 1001, and of structuring of insulating layer 1001.

In the shown example, insulating layer 903 is structured, for example by photolithography and etching, so as to only keep a portion of insulating layer 903 located vertically in line with the collector 303 and base 601 regions of bipolar transistor 100. In this example, the portion of insulating layer 903 remaining at the end of the structuring has, in top view, lateral dimensions strictly smaller than those of collector region 303.

Semiconductor layer 901 is, for example, then structured by etching, by using the portion of insulating layer 903 as a hard mask, so as to only keep a portion of semiconductor layer 901 located substantially vertically in line with the portion of insulating layer 903.

The portion of semiconductor layer 901 remaining at the end of the structuring forms an emitter region, for example an intrinsic emitter region, of bipolar transistor 100. In the shown example, the emitter region has, in top view, lateral dimensions strictly smaller than those of the collector region 303 of bipolar transistor 100.

Insulating layer 203 is, for example, then removed, for example by etching. During this step, portions of insulating layer 605 not coated with the portion of semiconductor layer 901 are, for example, also removed.

Insulating layer 1001 is then deposited on the side of surface 101T of semiconductor substrate 101, for example over the entire upper surface of the structure. Insulating layer 1001 coats insulating layer 201, semiconductor region 603, the portion of semiconductor layer 901, and the portion of insulating layer 903. In the shown example, insulating layer 1001 is more specifically located on top of and in contact with a surface of insulating layer 201 opposite to semiconductor substrate 101 (the upper surface of layer 201, in the orientation of FIG. 10), with portions of semiconductor region 603 not coated by insulating layer 605 or by semiconductor layer 901, with the flanks of the portion of semiconductor layer 901, and with the flanks and the upper face of the portion of insulating layer 903. Insulating layer 1001 is, for example, made of the same material as insulating layer 103. Insulating layer 1001 is, for example, made of an oxide, for example made of silicon oxide, for example tetraethyl orthosilicate.

Insulating layer 1001 is then structured, for example by photolithography and then etching, so as to only keep portions of insulating layer 1001 coating the flanks of the portions of semiconductor layer 901 and of insulating layer 903. The portions of insulating layer 903 and 1001 ensure, for example, a function of encapsulation of the portion of semiconductor layer 901.

FIG. 11 illustrates a structure subsequently obtained at the end of successive steps of removal of insulating layer 201 and of forming of a semiconductor layer 1101.

Semiconductor layer 1101 is, for example, formed by crystal growth from the portions of semiconductor layer 105 and from exposed flanks of base region 601 and of semiconductor region 603. In this example, semiconductor layer 1101 does not grow on the portions of insulating layers 1001 and 903. Semiconductor layer 1101 is, for example, made of the same material as semiconductor substrate 101, for example made of silicon. Semiconductor layer 1101 is, for example, doped with the second conductivity type—type P, in this example.

FIG. 12 illustrates a structure subsequently obtained at the end of a step of structuring of semiconductor layer 1101, of semiconductor layer 105, and of insulating layer 103.

Portions of semiconductor layer 1101, of semiconductor layer 105, and of insulating layer 103 located in the vicinity of the flanks of trench 109 are removed, for example by photolithography and then etching.

During this step, portions of semiconductor layer 1101 coating semiconductor region 603 are, for example, further removed. In the shown example, the portions of semiconductor layer 1101 are not in contact with the portions of insulating layer 1001.

The portions of semiconductor layer 1101 form, for example, an extrinsic base region of transistor 100.

FIG. 13 illustrates a structure subsequently obtained at the end of a step of forming of spacers 1301 laterally interposed between the portions of semiconductor layer 1101 and the portions of insulating layer 1001.

Each spacer 1301 comprises an insulating region 1303 coating semiconductor region 603. Insulating region 1303 is, for example, made of the same material as insulating layer 103. Insulating region 1303 is, for example, made of an oxide, for example a silicon oxide, for example tetraethyl orthosilicate.

Each spacer 1301 further comprises an insulating region 1305 coating insulating region 1303 and one of the portions of insulating layer 1001. Insulating region 1305 is, for example, made of the same material as insulating layer 201. Insulating region 1305 is, for example, made of a nitride, for example a silicon nitride.

In the shown example, insulating region 1303 is more specifically located on top of and in contact with the upper surface of semiconductor region 603, and insulating region 1305 is more specifically located on top of and in contact with the upper surface of insulating region 1303 and on top of and in contact with the portion of insulating layer 1001.

The forming of spacers 1301 is within the abilities of those skilled in the art based on the indications of the present disclosure.

Although this has not been detailed, other steps, for example steps of forming of contacting elements of transistor 100, may be implemented subsequently. Collector electrodes are, for example, formed on top of and in contact with portions of the upper surface 101T of semiconductor substrate 101 exposed at the end of the step previously described in relation with FIG. 13. Further, base electrodes are, for example, formed on top of and in contact with the upper surfaces of the portions of semiconductor layer 1101, and an emitter electrode is, for example, formed on top of and in contact with the upper surface of semiconductor region 901, for example after removal of insulating region 903 in order to expose the upper surface of semiconductor region 901. As an example, the electrodes of transistor 100 are formed by siliciding.

In bipolar transistor 100, the connection between intrinsic base 601 and extrinsic base, formed by the portions of semiconductor layer 1101, is located in an area of transistor 100 distant from a PN junction between base region 601 and collector region 303. This advantageously enables to decrease a capacitance C_{BC} between the base and the collector of transistor 100 without increasing a base resistance R_{Bx}. Bipolar transistor 100 thus has a higher switching frequency than transistors having a similar structure, but having a base region 601 which does not have larger lateral dimensions than collector region 303.

Many applications are likely to benefit from the advantages provided by bipolar transistor 100, and transistor 100 can thus be integrated into various types of devices.

As an example, transistor 100 can be integrated in a device for the automotive industry. The electrification of motor vehicles is causing a sharp increase in the number of electronic components present in vehicles. The device comprises, for example, thyristors, rectifiers, transient voltage suppressor diodes, modules, etc., intended to be incorporated in said vehicles. Further, driving assistance and driving automation have led to an increase in the number of electronic components in vehicles. The device comprises, for example, transient voltage suppressor diodes, an electrostatic discharge protection, and common-mode filters enabling to protect the device against electrical hazards. Transistor 100 may, for example, more particularly be integrated in a radar module enabling to implement adaptive cruise control and/or emergency braking functions of a vehicle.

As an example, transistor 100 can be integrated in a device intended for the industry. In particular, the device is, for example, used for the development of green energies or for the electrification of infrastructures, for example for charging stations or for the collection of solar energy. The device can also be used in the field of the Internet of Things or in the field of connected homes. The device can also be used for the implementation of cloud computing systems, of 5G radio frequency communication networks, of data centers, and of servers. The device comprises, for example, wide bandgap materials.

As an example, transistor 100 may be integrated in a device intended to be used in personal electronics, for example to increase a volume of information exchanged by radio frequency communication, in 5G communication systems, or more generally in any connected device. The device is, for example, a cell phone, or smartphone, or forms part of an Internet-of-Things network. The device is, for example, connected by 5G, by WiFi, or by broadband communication. The device comprises, for example, high-speed interfaces, for example with an advanced filtering and an electrostatic discharge protection.

As an example, transistor 100 may be integrated in a device intended to be uses in communications equipment, or in computers and peripherals. The device is, for example, used in 5G infrastructures and dedicated data centers. The device for example comprises silicon carbide diodes, Schottky power transistors, electrostatic discharge protections, and transient voltage suppressor diodes. The device may also be used in satellites comprising, for example, integrated passive devices for radio frequency applications.

Various embodiments and variants have been described. Those skilled in the art will understand that certain features of these various embodiments and variants may be combined, and other variants will occur to those skilled in the art. In particular, those skilled in the art are capable, based on the indications of the present disclosure, of adapting the method of manufacturing bipolar transistor 100 to the case where optional region 603 is omitted.

Finally, the practical implementation of the described embodiments and variants is within the abilities of those skilled in the art based on the functional indications given hereabove. In particular, the described embodiments are not limited to the specific examples of materials and of dimensions mentioned in the present disclosure.

1. A method of manufacturing a bipolar transistor, comprising the following successive steps:
a) depositing a stack on a surface of a semiconductor substrate, wherein the stack comprises a first insulating layer coating the semiconductor substrate and a second insulating layer coating the first insulating layer;
b) forming a trench extending across an entire thickness of the stack;
c) forming a collector region of the bipolar transistor in a first portion of the trench laterally delimited by the first insulating layer;
d) widening a second portion of the trench laterally delimited by the second insulating layer to form a widened portion of the trench; and
e) forming a base region of the bipolar transistor in the widened portion of the trench, said base region having lateral dimensions the widened portion of the trench which are greater than lateral dimensions of the collector region in the first portion of the trench.

2. The method according to claim 1, wherein c) forming the collector region comprises performing epitaxial growth from said surface of the semiconductor substrate.

3. The method according to claim 1, wherein the stack further comprises a third insulating layer coating the second insulating layer, a fourth insulating layer coating the third insulating layer, and a fifth insulating layer coating the fourth insulating layer.

4. The method according to claim 3, wherein:
the first, third, and fifth layers are made of a same first material; and
the second and fourth layers are made of a same second material, different from the first material.

5. The method according to claim 4, wherein the first material is an oxide.

6. The method according to claim 5, wherein the oxide is a silicon oxide.

7. The method according to claim 5, wherein the oxide is tetraethyl orthosilicate.

8. The method according to claim 4, wherein the second material is a nitride.

9. The method according to claim 8, wherein the nitride is a silicon nitride.

10. The method according to claim 3, wherein d) widening comprises further widening a third portion of the trench laterally delimited by the fourth insulating layer.

11. The method according to claim 3, further comprising, subsequently to d) widening, removing portions of the third insulating layer protruding into the trench.

12. The method according to claim 1, wherein e) forming the base region comprises performing epitaxial growth from a surface of the collector region opposite to the semiconductor substrate.

13. The method according to claim 12, wherein said epitaxial growth forming the base region extends laterally until reaching a flank of the trench.

14. The method according to claim 1, wherein d) widening comprises performing an isotropic etching.

15. The method according to claim 14, wherein isotropic etching is a wet etching.

16. A bipolar transistor, comprising:
a semiconductor substrate having a surface
a stack on the surface, wherein the stack comprises a first insulating layer coating the semiconductor substrate and a second insulating layer coating the first insulating layer;
a collector region of the bipolar transistor laterally delimited by the first insulating layer; and
a base region of the bipolar transistor on the collector region, wherein the base region has substantially vertical flanks and is laterally delimited by the second insulating layer; and
wherein the base region has, in top view, lateral dimensions strictly greater than lateral dimensions of the collector region.

17. The transistor according to claim 16, further comprising an emitter region having, in top view, lateral dimensions strictly smaller than the lateral dimensions of the collector region.

18. The transistor according to claim 16, comprising a trench extending through the stack, wherein the trench has a first width defining the lateral dimensions of the collector region and a second width, wider than the first width, defining the lateral dimensions of the base region.
